(19) United States
(12) Patent Application Publication
(10) Pub. No.: US 2025/0155112 A1
(43) Pub. Date: May 15, 2025

(54) POWER SUPPLY DEVICE FOR DOWNLIGHT

(71) Applicant: JOININ GLOBAL PTE.LTD., SG (SG)

(72) Inventor: Hongbing ZHENG, Hangzhou (CN)

(73) Assignee: JOININ GLOBAL PTE.LTD., SG (SG)

(21) Appl. No.: 18/624,171

(22) Filed: Apr. 2, 2024

(30) Foreign Application Priority Data
Nov. 13, 2023 (CN) 2023230559601

(51) Int. Cl. F21V 23/02; F21S 8/02

(52) U.S. Cl. CPC F21V 23/023; F21S 8/02

(57) ABSTRACT

A power supply device for a downlight is provided. The power supply device includes a junction box and a power supply box, and the junction box is configured to be detachably connected with the power supply box. The present disclosure enables the separation of the junction box from the power supply box, allowing the downlight to have independent wiring and power areas. The power supply box can fit inside the junction box during transportation, which greatly reduces the transportation space and enhances the protection of the power supply box.

### FIELD OF THE INVENTION

The present disclosure relates to the technical field of LED lighting, and in particular relates to a power supply device for a downlight.

### BACKGROUND OF THE INVENTION

LED downlights are lighting fixtures hidden in the ceiling, casting light downwards. They have a wide range of market applications, and are a popular choice for many spaces, including ceilings of bedrooms, living rooms, and bathrooms, where they blend seamlessly with the interior decor. LED downlights can create a variety of lighting effects using different light sources, light-guiding plates, or diffusers. They're compact, yet effective in enhancing the visual appeal and depth of a room through their play of light and shadow. If people want to make the space feel warmer and inviting, they can try installing more downlights to reduce the sense of pressure.

In North America, ultra-thin LED downlights usually have a separate power supply and lamp body. For safety reasons, the power supply is placed inside a metal junction box. The metal junction box serves two purposes. One is to protect the wires from being bitten or to avoid fire hazards caused by short circuits. The other is to insulate the power supply itself and avoid fire hazards in case of power supply malfunction. However, the current metal junction boxes require a large package and transportation space to meet the installation standards of downlights, resulting in inconvenient transportation.

### SUMMARY OF THE INVENTION

In view of the above-mentioned shortcomings, the present disclosure provides a power supply device for a downlight to solve the problem in related technology that the metal junction boxes are too large to be transported conveniently.

The power supply device includes a junction box and a power supply box, and the junction box is configured to be detachably connected with the power supply box.

The present disclosure enables the separation of the junction box from the power supply box, allowing the downlight to have independent wiring areas and power areas. The power supply box can fit inside the junction box during transportation, which greatly reduces the transportation space and enhances the protection of the power supply box.

In one embodiment, dimensions of the power supply box are smaller than those of the junction box.

In one embodiment, the junction box includes a box cover and a box body, and the box cover is rotatably connected with the box body. A side surface of the box body is provided with a first fixing member and a first positioning member. One side of the box body has an opening, and an end of the box cover close to the opening is provided with a first clamping member.

In one embodiment, an end of one side edge of the box body away from the opening has a first connecting hole, one side edge of the box cover has a first connecting member, and the first connecting member is matingly connected with the first connecting hole.

In one embodiment, the junction box includes a box cover and a box body, and the box cover is rotatably connected with the box body; wherein a side surface of the box body is provided with a first fixing member and a first positioning member; wherein one side of the box body has an opening; wherein an end of one side edge of the box body close to the opening has a first connecting hole, one side edge of the box cover has a first connecting member, and the first connecting member is matingly connected with the first connecting hole.

In one embodiment, a second fixing member is formed on an outer surface of the power supply box, and the second fixing member is configured to be matingly connected with the first fixing member.

In one embodiment, the first fixing member and the second fixing member are buckle components.

In one embodiment, the first fixing member and the second fixing member are sliding-guide components.

In one embodiment, a second positioning member is formed on an outer surface of the power supply box, and the second positioning member is configured to be matingly connected with the first positioning member.

In one embodiment, the first positioning member is disposed on the side surface of the box body, and the second positioning member is disposed on a side surface of the power supply box.

In one embodiment, the first positioning member is disposed on a bottom surface of the box body, and the second positioning member is disposed on a bottom surface of the power supply box.

In one embodiment, a slot is formed on one side of the power supply box, and the slot is configured to be matingly connected with the first clamping member on the box cover when the power supply box is partially inside the junction box.

In one embodiment, at least one third fixing member is formed on the box body and is configured to fix two adjacent side surfaces of the box body relative to each other.

In one embodiment, a first holding cavity is formed in the junction box for containing the power supply box; wherein a second holding cavity is formed in the power supply box for containing a power supply assembly of the downlight; wherein at least one fourth fixing member is formed in the second holding cavity for fixing the power supply assembly.

In one embodiment, the power supply box is made of plastic materials.

As described above, the power supply device of the present disclosure has the following beneficial effects:

1. The present disclosure enables the separation of the junction box from the power supply box, allowing the downlight to have independent wiring areas and power areas. The power supply box can fit inside the junction box during transportation, which greatly reduces the transportation space and enhances the protection of the power supply box.

2. The present disclosure enables different connection modes between the junction box and the power supply box, such as the utilization of buckle components, sliding-guide components, etc., which leads to shorter installation times, higher installation efficiency, and a better user experience. Also, the junction box and power supply box can be made of different materials, which adds more flexibility.

### BRIEF DESCRIPTION OF DRAWINGS

FIG. 1 shows a schematic structural diagram of a power supply device in one embodiment of the present disclosure.

FIG. 2 shows a schematic structural diagram of a junction box in one embodiment of the present disclosure.

FIG. 3 shows a schematic structural diagram of a junction box in another embodiment of the present disclosure.

FIG. 4 shows a schematic structural diagram of a box cover in one embodiment of the present disclosure.

FIG. 5 shows a schematic structural diagram of a box body in one embodiment of the present disclosure.

FIG. 6 shows a schematic structural diagram of a box body in another embodiment of the present disclosure.

FIG. 7 shows a schematic structural diagram of a power supply box in one embodiment of the present disclosure.

FIG. 8 shows a schematic structural diagram of a power supply box in another embodiment of the present disclosure.

FIG. 9 shows a schematic structural diagram of a power supply box in yet another embodiment of the present disclosure.

FIG. 10 shows a schematic structural diagram of a power supply device in another embodiment of the present disclosure.

FIG. 11 shows a schematic structural diagram of a power supply box in a further embodiment of the present disclosure.

FIG. 12 shows a schematic structural diagram of a junction box in yet another embodiment of the present disclosure.

FIG. 13 shows a schematic structural diagram of a box body in yet another embodiment of the present disclosure.

FIG. 14 shows a schematic structural diagram of a box cover in another embodiment of the present disclosure.

FIG. 15 shows a schematic structural diagram of a power supply box in yet another embodiment of the present disclosure.

FIG. 16 shows a schematic structural diagram of a power supply device in yet another embodiment of the present disclosure.

### REFERENCE NUMERALS

1 Power supply device for downlight
10 Junction box
110 Box cover
1110 First clamping member
1120 [symbol] 1120a [symbol] 1120b First connecting member
1130 [symbol] 1130a [symbol] 1130b Groove
120 Box body
1210 [symbol] 1210a [symbol] 1210b First fixing member
1220 [symbol] 1220a [symbol] 1220b First connecting hole
1230 [symbol] 1230a [symbol] 1230b Protruding buckle
1240 [symbol] 1240a [symbol] 1240b First positioning member
1250 Third fixing member
130 First holding cavity
20 Power supply box
210 Second fixing member
220 Slot
230 Second holding cavity
240 [symbol] 240a [symbol] 240b Second positioning member
2310 Fourth fixing member

### DETAILED DESCRIPTION OF THE INVENTION

The embodiments of the present disclosure will be described below. Those skilled can easily understand disclosure advantages and effects of the present disclosure according to contents disclosed by the specification. The present disclosure can also be implemented or applied through other different specific embodiments. Various details in this specification can also be modified or changed based on different viewpoints and applications without departing from the spirit of the present disclosure. It should be noted that the following embodiments and the features of the following embodiments can be combined with each other if no conflict will result.

It should be noted that the drawings provided in this disclosure only illustrate the basic concept of the present disclosure in a schematic way, so the drawings only show the components closely related to the present disclosure. The drawings are not necessarily drawn according to the number, shape, and size of the components in actual implementation; during the actual implementation, the type, quantity, and proportion of each component can be changed as needed, and the components' layout may also be more complicated.

The power supply device of the present disclosure solves the problem in related technology that the metal junction boxes are too large and inconvenient to transport.

The principle and implementation of the power supply device of the present disclosure will be described in detail below with reference to the accompanying drawings, so that the skilled person in the field can understand them without creative labor.

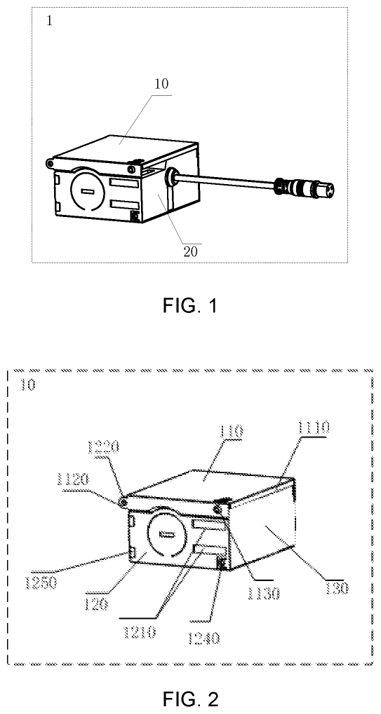

As shown in FIG. 1, the present disclosure provides a power supply device 1 for a downlight. The power supply device 1 includes a junction box 10 and a power supply box 20, and the junction box 10 is configured to be detachably connected with the power supply box 20.

Specifically, the present disclosure modularizes the junction box and enables the separation of the junction box from the power supply box. The power supply box can fit inside the junction box during transportation. When a user obtains the junction box, he/she can take out the power supply box from the junction box, and then detachably connect the power supply box with the junction box. Electrical wires may be placed in the junction box when the user installs and uses the downlight, which protects the wires from being bitten or avoids fire hazards caused by short circuits. A power supply assembly of the downlight is placed in the power supply box, which also avoids fire hazards caused by power supply malfunction.

The present disclosure enables the separation of the junction box from the power supply box, allowing the downlight to have independent wiring and power areas. The power supply box can fit inside the junction box during transportation, which greatly reduces the transportation space and enhances the protection of the power supply box.

In one embodiment, dimensions of the power supply box 20 are smaller than those of the junction box 10.

Specifically, the dimensions of the power supply box 20 are slightly smaller than those of the junction box 10, so that the power supply box may be placed in the junction box during transportation. This realizes the integration of the power supply box with the junction box during the packaging process, reducing the transportation space and facilitating the transportation.

As shown in FIG. 2, the junction box 10 includes a box cover 110 and a box body 120, and the box cover 110 is rotatably connected with the box body 120. A side surface of the box body 120 is provided with a first fixing member 1210 and a first positioning member 1240. The first fixing member 1210 and the first positioning member 1240 are both used for fixing the power supply box 20 and the junction box 10 relative to each other. One side of the box body 120 has an opening, and an end of the box cover 110 close to the opening is provided with a first clamping member 1110.

In one embodiment of the present disclosure, an end of one side edge of the box body away from the opening has a first connecting hole, one side edge of the box cover has a first connecting member, and the first connecting member is matingly connected with the first connecting hole. In some embodiments, there are two such first connecting holes and two such first connecting members.

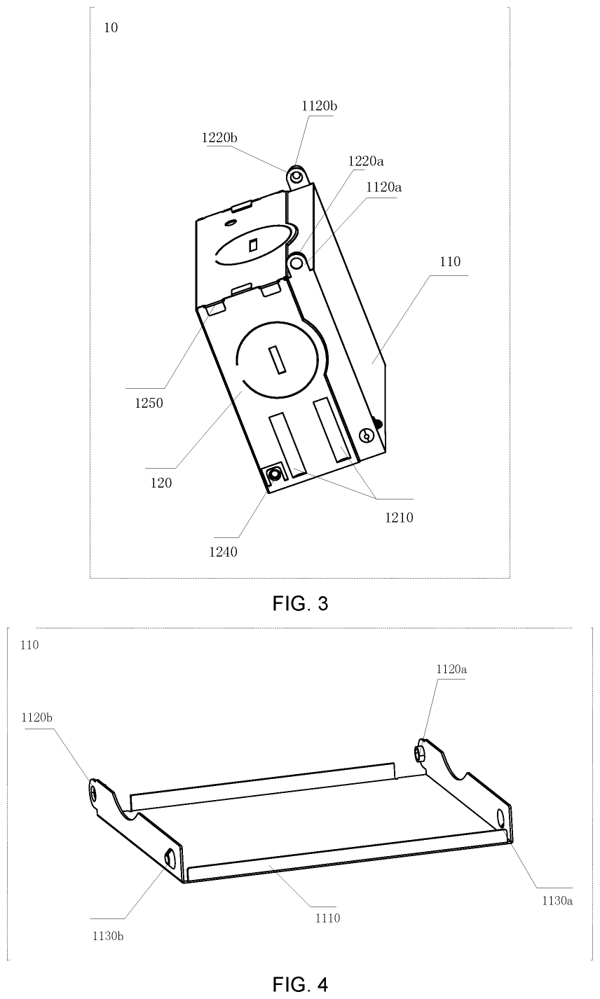

As shown in FIGS. 2 and 3, the box body 120 has two first connecting holes 1220 (such as a first connecting hole 1220a and a first connecting hole 1220b, as shown in FIG. 3), which are symmetrically disposed at two ends of the other side of the box body 120 opposite to the opening. The box cover 110 has two first connecting members 1120 (such as a first connecting member 1120a and a first connecting member 1120b, as shown in FIG. 3), which are matingly connected with the two first connecting holes 1220, respectively. The first connecting hole 1220a shares a same axis with the first connecting hole 1220b, so that the box cover 110 can be rotatably connected to the box body 120, and rotatably around this axis.

It should be noted that the two first connecting members 1120 are buckles or elongated iron sheets, and correspondingly match the first connecting holes 1220 in shape. The first connecting members 1120 and first connecting holes 1220 can be shaped as needed; for example, the first connecting members 1120 and the first connecting holes 1220 may be hinge components, joint bearing components, etc.

As shown in FIG. 2, at least one groove 1130 (such as a groove 1130a and a groove 1130b, as shown in FIG. 4, which shows a schematic structural diagram of the box cover) is formed on a side surface of the box cover 110, and at least one protruding buckle 1230 is formed on a side surface of the box body 120. The number and shape of the grooves 1130 correspond to those of the protruding buckles 1230. That is, each of the grooves 1130 is configured to be matingly connected with one of the protruding buckles 1230.

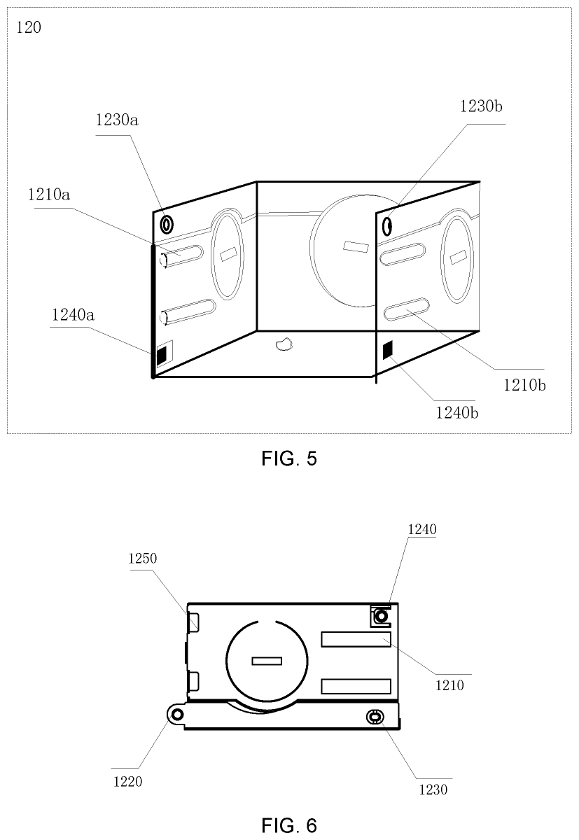

Please refer to FIGS. 5 and 6, both of which are schematic structural diagrams showing the box body 120. The box body 120 is provided with two protruding buckles 1230 (such as a protruding buckle 1230a and a protruding buckle 1230b, as shown in FIG. 5), which are symmetrically disposed on two side surfaces of the box body 120 adjacent to the opening.

When the box cover 110 covers the box body 120, the grooves 1130a and 1130b are matingly connected to the protruding buckles 1230a and 1230b, respectively, so as to fix the box cover 110 and the box body 120 relative to each other.

As shown in FIG. 5, the two side surfaces of the box body 120 adjacent to the opening are provided with a first fixing member 1210a and a first fixing member 1210b, respectively. The first fixing members 1210a and 1210b are configured to be fixedly connected with the power supply box 20, and are disposed below the corresponding protruding buckles 1230a and 1230b, respectively.

In addition, each of the two side surfaces of the box body 120 adjacent to the opening may be provided with two or more first fixing members, thereby realizing a stronger connection between the power supply box 20 and the junction box 10.

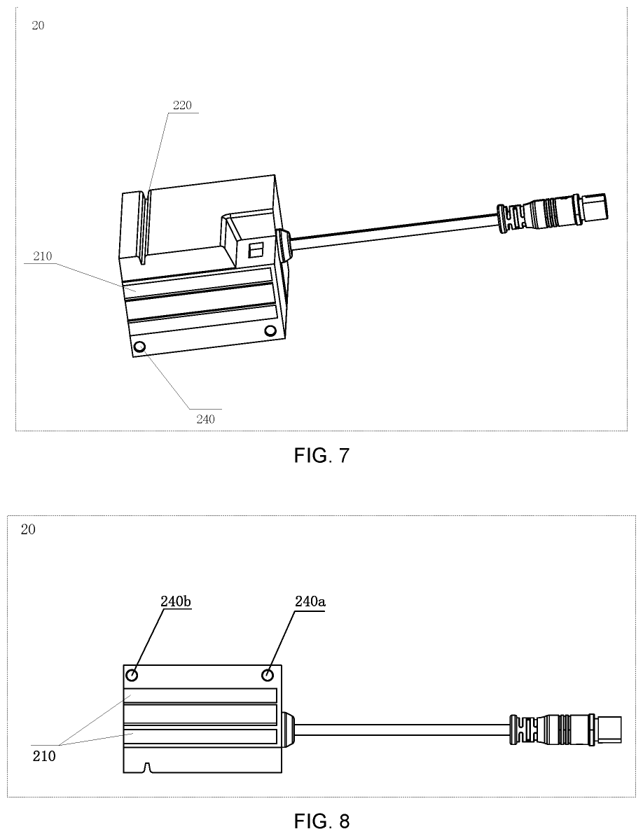

In one embodiment, as shown in FIG. 7, a second fixing member 210 is formed on an outer surface of the power supply box 20, and the second fixing member 210 is configured to be matingly connected with the first fixing member 1210.

Specifically, the number and shape of the second fixing members 210 correspond to those of the first fixing members. That is, each of the second fixing members 210 is configured to be matingly connected with one of the first fixing members. FIG. 8 shows a schematic structural diagram of one side surface of the power supply box according to the present disclosure.

In one embodiment, the first fixing member 1210 and the second fixing member 210 are buckle components.

Specifically, the first fixing member 1210 may be a slot, and the second fixing member 210 may be a buckle. Also, the first fixing member 1210 may be a buckle, and the second fixing member 210 may be a slot.

In one embodiment, the first fixing member 1210 and the second fixing member 210 are sliding-guide components.

In the present disclosure, the junction box 10 is detachably connected with the power supply box 20 through the first fixing member 1210 and the second fixing member 210. When connected, the junction box 10 and the power supply box 20 form a drawer-like structure. During transportation, the power supply box 20 is pushed within the junction box 10 (as shown in FIG. 1, which shows a schematic diagram of a structure where the power supply box 20 is completely placed in the junction box 10). When the user installs the downlight, the power supply box 20 is partially pulled out of the junction box 10, and is fixedly connected with the junction box 10 by matching a slot 220 on the power supply box 20 with the first clamping member 1110 on the box cover, thus the user can perform an installation of the downlight.

It should be noted that the structures of the first fixing member 1210 and the second fixing member 210 can be adjusted according to actual needs.

As shown in FIG. 6, a first positioning member 1240 is formed on a side surface of the box body 120, and is configured to be fixedly connected with the power supply box 20.

As shown in FIG. 7, a second positioning member 240 is formed on an outer surface of the power supply box 20, and is configured to be matingly connected with the first positioning member 1240.

In one embodiment of the present disclosure, the first positioning member is disposed on the side surface of the box body, and the second positioning member is disposed on the side surface of the power supply box.

Specifically, the outer surface of the power supply box 20, on which the second positioning member 240 is formed, is fixedly connected with the junction box 10. In some embodiments, there are more than one such outer surfaces, and the number of second positioning members 240 on each of the outer surfaces is two, and the two second positioning members 240 are disposed at two ends of this outer surface, respectively (such as a second positioning member 240a and a second positioning member 240b, as shown in FIG. 8). Therefore, the power supply box 20 and the junction box 10 can be fixedly connected either in the process of packaging and transportation or in the process of installation and use, which prevents the power supply box 20 from sliding inside the junction box 10 or sliding out of the junction box 10.

More specifically, the junction box 10 is detachably connected with the power supply box 20 through the first fixing member 1210 and the second fixing member 210. When connected, the junction box 10 and the power supply box 20 form a drawer-like structure. During transportation, the power supply box 20 is pushed within the junction box 10 (as shown in FIG. 1, which shows a schematic diagram of a structure where the power supply box 20 is completely placed in the junction box 10), and the first positioning member 1240 is fixedly connected with the second positioning member 240a, preventing the power supply box 20 from sliding inside the junction box 10. When the user installs the downlight, the power supply box 20 is first partially pulled out of the junction box 10, and then the first positioning member 1240 is fixedly connected with the second positioning member 240b, so that the user can perform an installation of the downlight.

In one embodiment, as shown in FIG. 7, a slot 220 is formed on an end portion of the power supply box 20, and this end portion is inside the junction box 10 when the power supply box 20 is partially inside the junction box 220, and the slot 220 is configured to be matingly connected with the first clamping member 1110 on the box cover 110 when the power supply box 20 is partially inside the junction box 220.

Specifically, the slot 220 is shaped to match the first clamping member 1110, as shown in FIG. 7, and the length of the slot 220 extends from one side of the end portion to an opposing side of the end portion, that is, the slot 220 is exposed by these two sides. When the user installs the downlight, the power supply box 20 is partially pulled out of the junction box 10, and is fixedly connected with the junction box 10 by adjusting relative orientation of the junction box 10 and the power supply box 20, if needed, and matching the slot 220 with the first clamping member 1110, which prevents the power supply box 20 from sliding out of the junction box 10 after installation.

In one embodiment, as shown in FIG. 2, a first holding cavity 130 is formed in the junction box 10, and is for containing the power supply box 20.

Specifically, the power supply box 20 is placed in the first holding cavity 130 in the process of packaging and transportation, which reduces the transportation space and facilitates the transportation. When the user installs the downlight, the first holding cavity 130 is configured to accommodate electrical wires, which protects the wires from being bitten or avoids fire hazards caused by short circuits.

As shown in FIG. 6, at least one third fixing member 1250 is formed on the box body and is configured to fix two adjacent side surfaces of the box body relative to each other.

It should be noted that the box body may be provided with two or more third fixing members 1250, so that the junction box can be further reinforced.

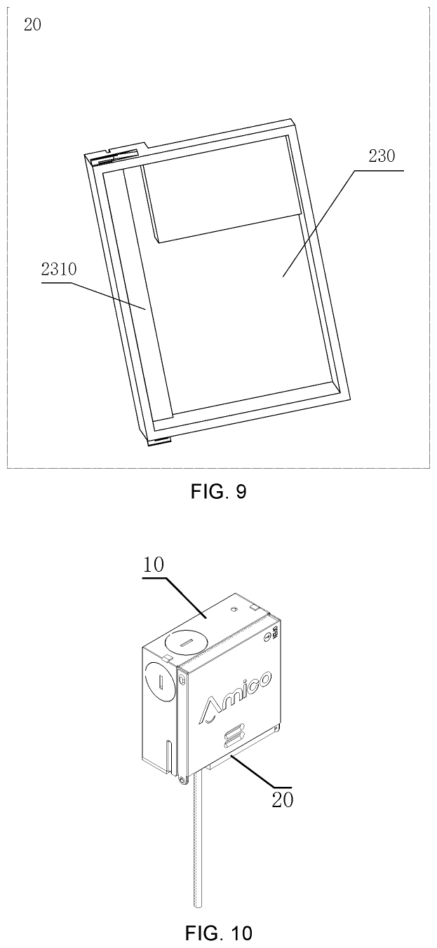

In one embodiment, as shown in FIG. 9, a second holding cavity 230 is formed in the power supply box 20 for containing a power supply assembly of the downlight. At least one fourth fixing member is formed in the second holding cavity 230 for fixing the power supply assembly.

Specifically, the number and shape of the fourth fixing members can be adjusted based on the actual power supply assembly. Existing power supply boxes are made of metal materials, and power supply assemblies are not suitable for being directly housed in the metal boxes. While in the present disclosure the power supply box is made of plastic materials, and the power supply assembly can be fixedly installed in the power supply box through the fourth fixing member, thereby greatly improving the flexibility of use.

It should be noted that the power supply assembly may be one or more of switch controllers, inductors, switch elements, feedback resistors, input filter elements, output filter elements, and other devices.

In one embodiment, the power supply box 20 is made of plastic materials.

It should be noted that a plastic power supply box 20 can help to better secure the power supply assembly. The junction box 10 is made of metal materials, and when the user installs and uses the downlight, the electrical wires may be placed in the junction box, which protects the wires from being bitten or avoids fire hazards caused by short circuits.

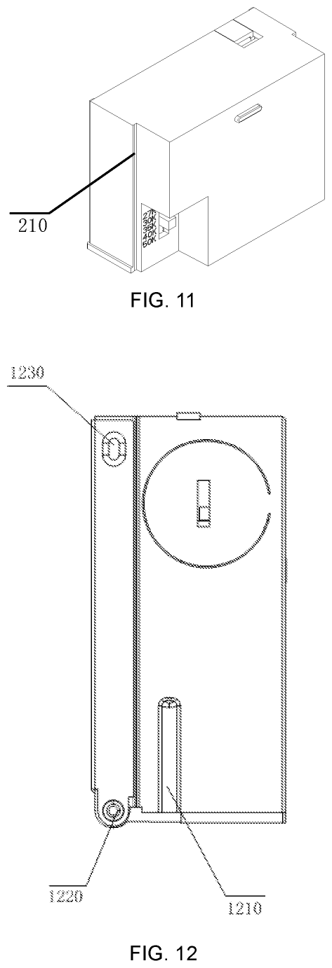

FIG. 10 shows a schematic structural diagram of a power supply device in one embodiment of the present disclosure. FIG. 11 shows a schematic structural diagram of a power supply box in FIG. 10, while FIG. 12 shows a schematic structural diagram of the junction box in FIG. 10.

As shown in FIGS. 11 and 12, in one embodiment of the present disclosure, the second fixing member 210 is right-angled slide grooves on both side edges of the power supply box, while the first fixing member 1210 is slide rails on both side edges of the box body 120. The second fixing member 210 is matingly connected with the first fixing member 1210, and is linearly distributed along the side edge of the power supply box, allowing the installation of a set of slide rail components on each side, to meet user requirements.

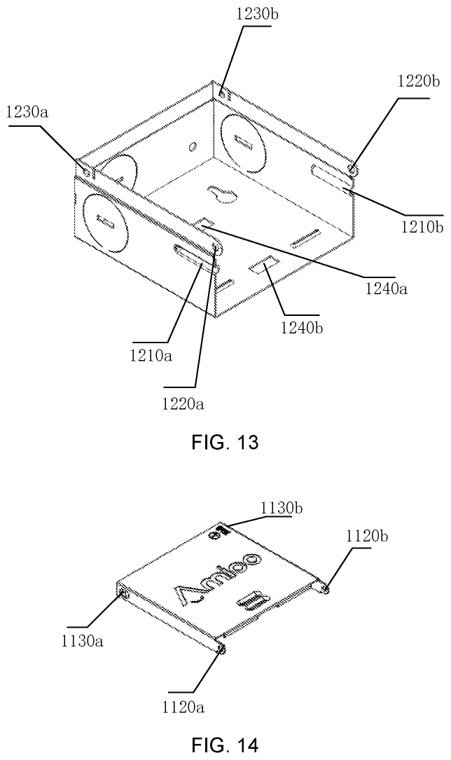

As shown in FIGS. 12 and 13, the box body 120 has two first connecting holes 1220 (such as a first connecting hole 1220a and a first connecting hole 1220b, as shown in FIG. 13), which are symmetrically disposed at two ends of the two side surfaces of the box body 120 adjacent to the opening, respectively.

In one embodiment of the present disclosure, an end of one side edge of the box body close to the opening has a first connecting hole, one side edge of the box cover has a first connecting member, and the first connecting member is matingly connected with the first connecting hole.

As shown in FIG. 14, the box cover 110 has two first connecting members 1120 (such as a first connecting member 1120a and a first connecting member 1120b), which are matingly connected with the two first connecting holes 1220, respectively. The first connecting hole 1220a shares a same axis with the first connecting hole 1220b, so that the box cover 110 can be rotatably connected to the box body 120, and rotatably around this axis.

It should be noted that the two first connecting members 1120 are buckles or elongated iron sheets, and correspondingly match the first connecting holes 1220 in shape. The first connecting members 1120 and first connecting holes 1220 can be shaped as needed; for example, the first connecting members 1120 and the first connecting holes 1220 may be hinge components, joint bearing components, etc.

As shown in FIG. 12, the box body 120 is provided with two protruding buckles 1230 (such as a protruding buckle 1230a and a protruding buckle 1230b, as shown in FIG. 13), which are symmetrically disposed on the other ends of the same side surfaces as the first connecting holes 1220.

As shown in FIG. 14, at least one groove 1130 (such as a groove 1130a and a groove 1130b, as shown in FIG. 14) is formed on the side surface of the box cover 110, and at least one protruding buckle 1230 is formed on the side surface of the box body 120. The number and shape of the grooves 1130 correspond to those of the protruding buckles 1230. That is, each of the grooves 1130 is configured to be matingly connected with one of the protruding buckles 1230.

It should be noted that when lifted, the box cover 110 can rotate around the first connecting members, at which time, the angle between the box cover 110 and the box body 120 faces away from the opening of the entire junction box, facilitating the installation of the power supply device by users.

In one embodiment of the present disclosure, the first positioning member is disposed on a bottom surface of the box body, and the second positioning member is disposed on a bottom surface of the power supply box.

As shown in FIG. 13, at least one first positioning member 1240 (such as a first positioning member 1240a and a first positioning member 1240b) is formed at two ends of the bottom surface of the box body 120.

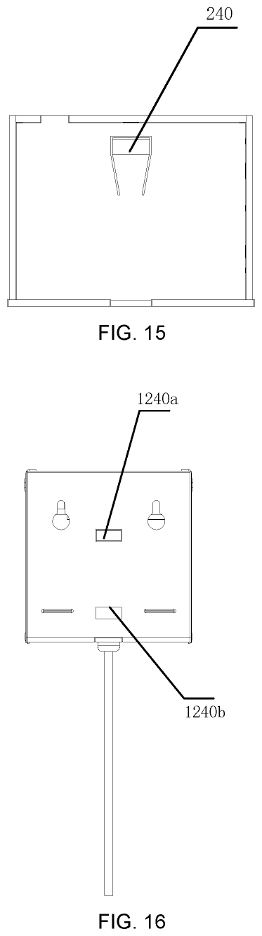

As shown in FIG. 15, the second positioning member 240 is disposed on the bottom surface of the power supply box 20.

Specifically, when connected, the junction box 10 and the power supply box 20 form a drawer-like structure. During transportation, the power supply box 20 is pushed within the junction box (as shown in FIG. 10), at which time the first positioning member 1240 is fixedly connected with the second positioning member 240, preventing the power supply box from sliding inside the junction box. When the user installs the downlight, the power supply box is first partially pulled out of the junction box, and then the first positioning member 1240 is fixedly connected with the second positioning member 240, so that the user can perform an installation of the downlight. FIG. 16 shows a schematic diagram of a bottom surface of the junction box when the power supply box is disposed within the junction box.

In addition, the cuboid structures of the junction box 10 and power supply box 20 are only illustrative and not restrictive, and other reasonable structures may also be applicable according to actual needs.

In summary, the power supply device of the present disclosure enables the separation of the junction box from the power supply box, allowing the downlight to have independent wiring areas and power areas. The power supply box can fit inside the junction box during transportation, which greatly reduces the transportation space and enhances the protection of the power supply box. The present disclosure enables different connection modes between the junction box and the power supply box, such as the utilization of buckle components, sliding-guide components, etc., which leads to shorter installation times, higher installation efficiency, and a better user experience. Also, the junction box and power supply box can be made of different materials, which adds more flexibility.

The descriptions of the steps or structures corresponding to the drawings are respectively emphasized, and some steps or structures that are not detailed can be referred to the relevant descriptions of other steps or structures.

The above-mentioned embodiments are merely illustrative of the principle and effects of the present disclosure instead of limiting the present disclosure. Those skilled in the art can make modifications or changes to the above-mentioned embodiments without going against the spirit and the range of the present disclosure. Therefore, all equivalent modifications or changes made by those who have common knowledge in the art without departing from the spirit and technical concept disclosed by the present disclosure shall be still covered by the claims of the present disclosure.

1. A power supply device for a downlight, including a junction box and a power supply box, wherein the junction box is configured to be detachably connected with the power supply box.

2. The power supply device according to claim 1, wherein dimensions of the power supply box are smaller than those of the junction box.

3. The power supply device according to claim 1, wherein the junction box includes a box cover and a box body, and the box cover is rotatably connected with the box body; wherein a side surface of the box body is provided with a first fixing member and a first positioning member; wherein one side of the box body has an opening, and an end of the box cover close to the opening is provided with a first clamping member.

4. The power supply device according to claim 3, wherein an end of one side edge of the box body away from the opening has a first connecting hole, one side edge of the box cover has a first connecting member, and the first connecting member is matingly connected with the first connecting hole.

5. The power supply device according to claim 1, wherein the junction box includes a box cover and a box body, and the box cover is rotatably connected with the box body; wherein a side surface of the box body is provided with a first fixing member and a first positioning member; wherein one side of the box body has an opening; wherein an end of one side edge of the box body close to the opening has a first connecting hole, one side edge of the box cover has a first connecting member, and the first connecting member is matingly connected with the first connecting hole.

6. The power supply device according to claim 4 or 5, wherein a second fixing member is formed on an outer surface of the power supply box, and the second fixing member is configured to be matingly connected with the first fixing member.

7. The power supply device according to claim 6, wherein the first fixing member and the second fixing member are buckle components.

8. The power supply device according to claim 6, wherein the first fixing member and the second fixing member are sliding-guide components.

9. The power supply device according to claim 4 or 5, wherein a second positioning member is formed on an outer surface of the power supply box, and the second positioning member is configured to be matingly connected with the first positioning member.

10. The power supply device according to claim 9, wherein the first positioning member is disposed on the side surface of the box body, and the second positioning member is disposed on a side surface of the power supply box.

11. The power supply device according to claim 9, wherein the first positioning member is disposed on a bottom surface of the box body, and the second positioning member is disposed on a bottom surface of the power supply box.

12. The power supply device according to claim 4, wherein a slot is formed on one side of the power supply box, and the slot is configured to be matingly connected with the first clamping member on the box cover when the power supply box is partially inside the junction box.

13. The power supply device according to claim 4 or 5, wherein at least one third fixing member is formed on the box body and is configured to fix two adjacent side surfaces of the box body relative to each other.

14. The power supply device according to claim 1, wherein a first holding cavity is formed in the junction box for containing the power supply box; wherein a second holding cavity is formed in the power supply box for containing a power supply assembly of the downlight; wherein at least one fourth fixing member is formed in the second holding cavity for fixing the power supply assembly.

15. The power supply device according to claim 5, wherein a second fixing member is formed on an outer surface of the power supply box, and the second fixing member is configured to be matingly connected with the first fixing member.

16. The power supply device according to claim 15, wherein the first fixing member and the second fixing member are buckle components, or the first fixing member and the second fixing member are sliding-guide components.

17. The power supply device according to claim 5, wherein a second positioning member is formed on an outer surface of the power supply box, and the second positioning member is configured to be matingly connected with the first positioning member.

18. The power supply device according to claim 17, wherein the first positioning member is disposed on the side surface of the box body, and the second positioning member is disposed on a side surface of the power supply box.

19. The power supply device according to claim 17, wherein the first positioning member is disposed on a bottom surface of the box body, and the second positioning member is disposed on a bottom surface of the power supply box.

20. The power supply device according to claim 5, wherein at least one third fixing member is formed on the box body and is configured to fix two adjacent side surfaces of the box body relative to each other.
